(19) United States
(12) Patent Application Publication
(10) Pub. No.: US 2025/0291241 A1
(43) Pub. Date: Sep. 18, 2025

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Hyeonil JUNG, Suwon-si (KR); Shinhyo BAE, Suwon-si (KR); Hyungseok Park, Suwon-si (KR); Sungeun Lee, Suwon-si (KR); Youngmin Kim, Suwon-si (KR); Jaechul Lee, Suwon-si (KR); Huiseon Choe, Suwon-si (KR); Minji So, Suwon-si (KR)

(21) Appl. No.: 19/073,275

(22) Filed: Mar. 7, 2025

(30) Foreign Application Priority Data
Mar. 13, 2024 (KR) 10-2024-0035455

(51) Int. Cl. G03F 1/00; C08G 61/10; C08G 61/12; H01L 21/311

(52) U.S. Cl. CPC G03F 1/00; C08G 61/10; C08G 61/124; H01L 21/31144; C08G 2261/124; C08G 2261/1422; C08G 2261/148; C08G 2261/312; C08G 2261/314; C08G 2261/3241; C08G 2261/42

(57) ABSTRACT

A hardmask composition, a hardmask layer that is manufactured from the hardmask composition, and a method of forming patterns by using the hardmask layer manufactured from the hardmask composition, the hardmask composition includes a polymer including a structural unit represented by Chemical Formula 1; and a solvent,

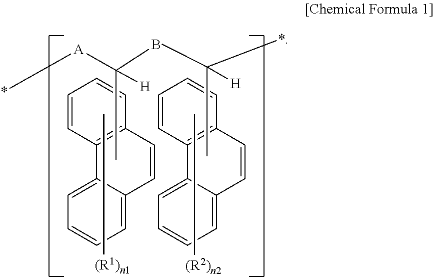

### CROSS-REFERENCE TO RELATED APPLICATION

This application claims priority to and the benefit of Korean Patent Application No. 10-2024-0035455 filed in the Korean Intellectual Property Office on Mar. 13, 2024, the entire contents of which are incorporated herein by reference.

### BACKGROUND

### 1. Field

Embodiments relate to a hardmask composition, a hardmask layer including a cured product of the hardmask composition, and a method of forming a pattern using the hardmask composition.

### 2. Description of the Related Art

Recently, the semiconductor industry has developed to an ultra-fine technique having a pattern of several to several tens of nanometer size. Such ultrafine technique may utilize effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a polymer including a structural unit represented by Chemical Formula 1; and a solvent,

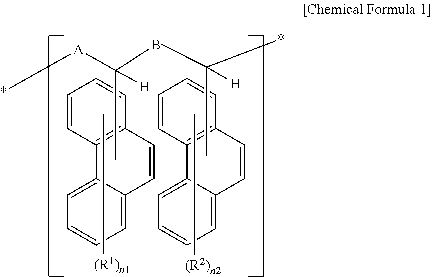

wherein, in Chemical Formula 1, A is a substituted or unsubstituted moiety of Group 1, B is a substituted or unsubstituted phenylenyl group or a substituted or unsubstituted naphthalenyl group, R¹ and R² are each independently deuterium, a hydroxy group, a halogen atom, —NR^{a}R^{b}, in which R^{a} and R^{b} are each independently hydrogen, deuterium, a substituted or unsubstituted C1 to C10 alkyl group, or a substituted or unsubstituted C6 to C20 aryl group, a substituted or unsubstituted C1 to C20 alkoxy group, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic hydrocarbon group, a substituted or unsubstituted C6 to C30 hetero aromatic hydrocarbon group, or a combination thereof, n1 and n2 are each independently an integer of 0 to 9, and * is a linking point,

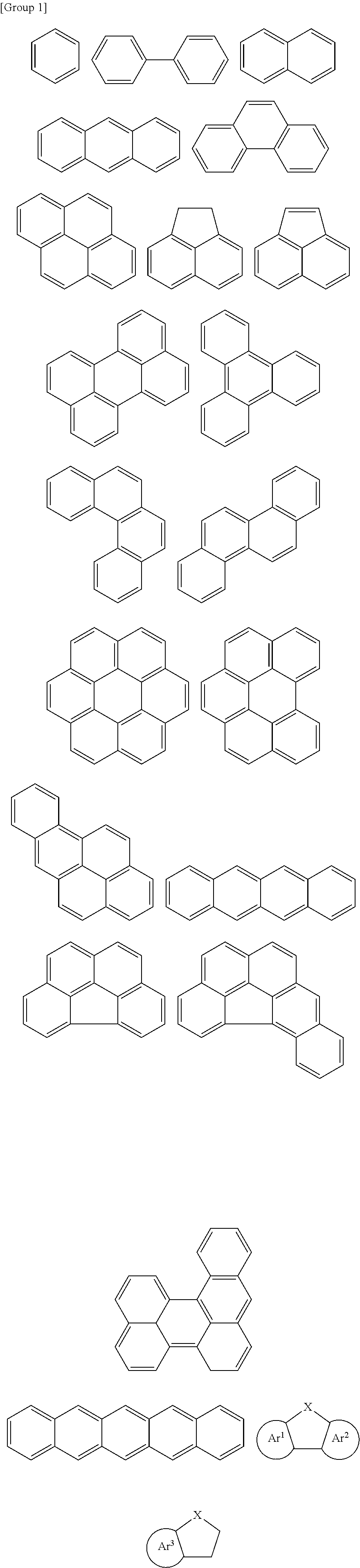

wherein, in Group 1, Ar¹ to Ar³ are each independently a substituted or unsubstituted C6 to C20 aromatic ring group, X is —CR^{c}R^{d}—, —N(R^{e})—, —B(R^{f})—, —P(R^{g})—, —O—, or —S—, and R^{e} to R^{g} are each independently hydrogen, deuterium, a substituted or unsubstituted C1 to C10 alkyl group, a substituted or unsubstituted C6 to C20 aryl group, or a combination thereof.

The embodiments may be realized by providing a hardmask layer comprising a cured product of the aforementioned hardmask composition according to an embodiment.

The embodiments may be realized by providing a method of forming patterns, the method including providing a material layer on a substrate, applying the hardmask composition according to an embodiment to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed part of the material layer.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B.

As used herein, when a definition is not otherwise provided, “substituted” may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, when a definition is not otherwise provided, “aromatic hydrocarbon ring” refers to a group including at least one hydrocarbon aromatic moiety, and includes a form in which hydrocarbon aromatic moieties are linked by a single bond, a non-aromatic fused ring form in which hydrocarbon aromatic moieties are fused directly or indirectly, or a combination thereof as well as a non-fused aromatic hydrocarbon ring or a condensed aromatic hydrocarbon ring.

More specifically, a substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

As used herein, when a definition is not otherwise provided, “hetero” refers to one or more heteroatoms selected from N, O, S, Se, and P.

As used herein, when a definition is not otherwise provided, “heteroaromatic ring” refers to a ring including at least one hetero atom selected from N, O, S, Se, and P within an aromatic hydrocarbon ring.

More specifically, the substituted or unsubstituted hetero aromatic ring may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, pyridoindolyl group, benzopyridooxazinyl group, benzopyridothiazinyl group, 9,9-dimethyl-9,10-dihydroacridinyl group, a combination thereof, or a combined fused ring of the foregoing groups, but is not limited thereto.

As used herein, when a definition is not otherwise provided, “combination” means mixing or copolymerization.

As used herein, when a definition is not otherwise provided, “polymer” may include both oligomers and polymers.

As used herein, when a definition is not otherwise provided, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

There is a constant trend in a semiconductor industry to reduce a size of chips. In order to respond to this, the line width of the resist patterned in lithography technology should be tens of nanometers or smaller in size. Accordingly, a height that can withstand the line width of the resist pattern could be limited, and there are cases where the resists may not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching, and therefore, the hardmask layer may have etch resistance and crosslinking characteristics to withstand the etching process required for pattern transfer.

Some hardmask layers may be formed in a chemical or physical deposition method and could have low economic efficiency due to a large-scale equipment and a high process cost. Therefore, a method of forming a hardmask layer by a spin-coating technique has recently been developed. The spin-coating technique may be easier to process than the conventional method and in addition, may help secure excellent gap-fill characteristics and planarization characteristics of a hardmask layer formed therefrom. In a hardmask layer formed using the spin-coating technique, the required etch resistance could be somewhat lowered. Accordingly, a desirable hardmask composition may be applied using the spin-coating technique and may secure equivalent etch resistance to that of the hardmask layer formed in the chemical or physical deposition method.

In order to improve the etch resistance of the hardmask layer, maximizing a carbon content of a hardmask composition has been considered. However, as a carbon content of a polymer included in the hardmask composition is maximized, solubility in solvents tends to decrease. Accordingly, the carbon content maximization of a polymer included in the hardmask composition may not only improve the etch resistance of the hardmask layer formed of the hardmask composition but should also secure high solubility of the polymer in the solvents.

The hardmask composition according to some embodiments may include a polymer including an aromatic hydrocarbon ring or a heteroaromatic ring, thereby maximizing a carbon content in the polymer, and ensuring excellent etch resistance of the hardmask layer formed therefrom. In addition, by including a polar functional group in the polymer, the solubility of the polymer in the solvent may be increased and the film density of the hardmask layer formed therefrom may be improved. In addition, by including tertiary carbon and a phenanthryl group connected thereto in the polymer, not only does it further increase the carbon content in the polymer, but also, due to the low extinction coefficient (k) of the phenanthryl group at the exposure wavelength, the hardmask layer formed from the composition including the polymer may be formed to a high thickness.

In an implementation, the hardmask composition according to some embodiments may include, e.g., a polymer including a structural unit represented by Chemical Formula 1, and a solvent.

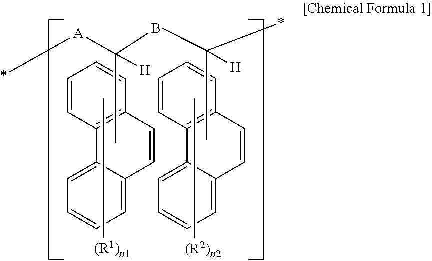

In Chemical Formula 1, A may be or may include, e.g., a substituted or unsubstituted moiety of Group 1.

B may be or may include, e.g., a substituted or unsubstituted phenylene group or a substituted or unsubstituted naphthalenyl group.

R¹ and R² may each independently be or include, e.g., deuterium, a hydroxy group, a halogen atom, —NR^{a}R^{b} (in which R^{a} and R^{b} are each independently hydrogen, deuterium, a substituted or unsubstituted C1 to C10 alkyl group, or a substituted or unsubstituted C6 to C20 aryl group), a substituted or unsubstituted C1 to C20 alkoxy group, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic hydrocarbon group, a substituted or unsubstituted C6 to C30 hetero aromatic hydrocarbon group, or a combination thereof.

n1 and n2 may each independently be, e.g., an integer of 0 to 9. In an implementation, when n1 or n2 are 0, R¹ and R² may not be present and the phenanthrenyl group may be unsubstituted (may only include hydrogen atoms thereon).

* is a linking point:

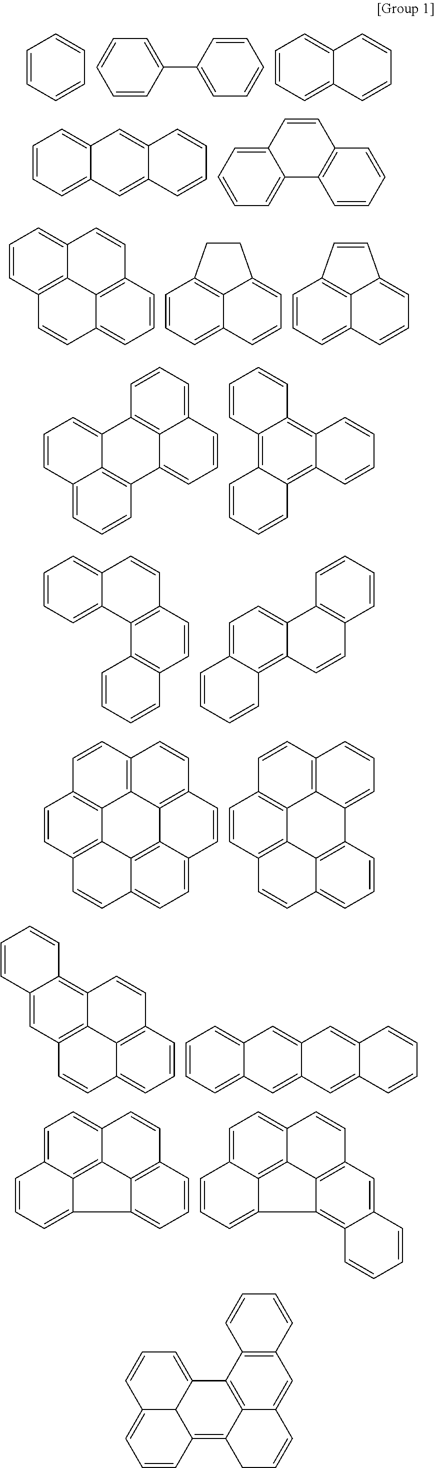

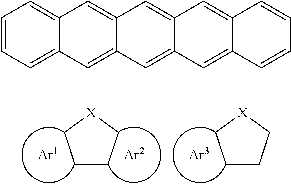

In Group 1, Ar¹ to Ar³ may each independently be, e.g., a substituted or unsubstituted C6 to C20 aromatic ring.

X may be, e.g., —CR^{c}R^{d}—, —N(R^{e})—, —B(R^{f})—, —P(R^{g})—, —O—, or —S—, and

R^{e} to R^{g} may each independently be, e.g., hydrogen, deuterium, a substituted or unsubstituted C1 to C10 alkyl group, a substituted or unsubstituted C6 to C20 aryl group, or a combination thereof.

In an implementation, the aromatic hydrocarbon ring or heteroaromatic ring in the structural unit may be substituted with a polar substituent. In this case, the solubility of the polymer in the solvent may be further improved. Examples of polar substituents may include a hydroxy group, an alkoxy group, and an amino group. In addition, by including the polar group, a polar bond or a hydrogen bond between polymers may be formed, and the hardmask layer formed therefrom may have a higher film density and further improved pattern formation properties.

In an implementation, A may be, e.g., a substituted or unsubstituted moiety of Group 1-1.

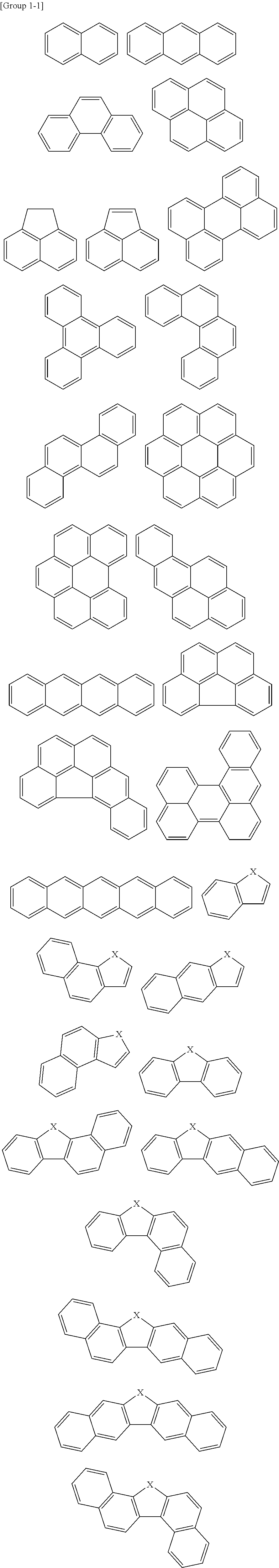

In Group 1-1, X may be, e.g., —CR^{c}R^{d}—, —N(R^{e})—, —O—, or —S—, for example, —CR^{c}R^{d}—, or —N(R^{e})—, for example, —N(R^{e})—. R^{c} to R^{e} may each independently be, e.g., hydrogen, deuterium, a substituted or unsubstituted C1 to C10 alkyl group, a substituted or unsubstituted C6 to C20 aryl group, or a combination thereof. In an implementation, A may be, e.g., a substituted or unsubstituted moiety of Group 1-2.

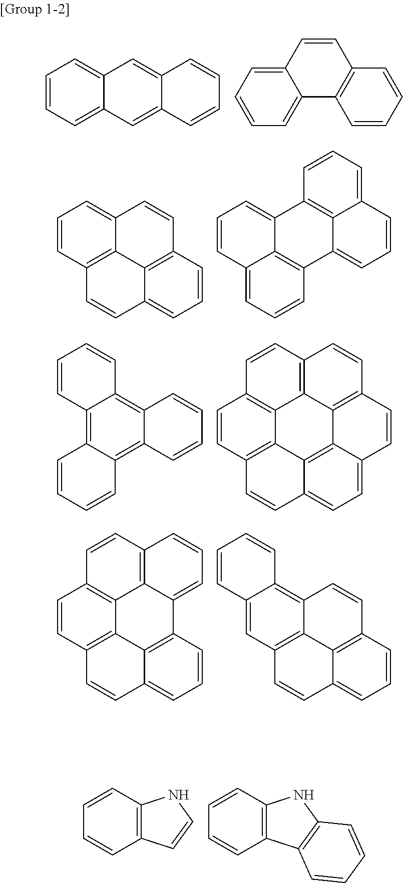

In an implementation, R¹ and R² may each independently be, e.g., deuterium, a hydroxy group, a halogen atom, —NR^{a}R^{b} (in which R^{a} and R^{b} are each independently hydrogen, deuterium, or a substituted or unsubstituted C1 to C10 alkyl group), a substituted or unsubstituted C1 to C20 alkoxy group, a substituted or unsubstituted C1 to C20 alkyl group, a substituted or unsubstituted C2 to C20 alkenyl group, a substituted or unsubstituted C3 to C20 cycloalkyl group, a substituted or unsubstituted C3 to C20 cycloalkenyl group, a substituted or unsubstituted C1 to C20 heteroalkyl group, a substituted or unsubstituted C2 to C20 heterocycloalkyl group, a substituted or unsubstituted C6 to C30 aryl group, a substituted or unsubstituted C2 to C20 heteroaryl group, or a combination thereof. In an implementation, R¹ and R² may each independently be, e.g., deuterium, a hydroxy group, a halogen atom, a substituted or unsubstituted C1 to C20 alkoxy group, a substituted or unsubstituted C1 to C20 alkyl group, a substituted or unsubstituted C6 to C20 aryl group, or a combination thereof.

In an implementation, in Chemical Formula 1, n1 and n2 may each independently be, e.g., an integer from 0 to 7, an integer from 0 to 4, 0 or 1.

In an implementation, Chemical Formula 1 may be represented by, e.g., one of Chemical Formula 1-1 to Chemical Formula 1-4.

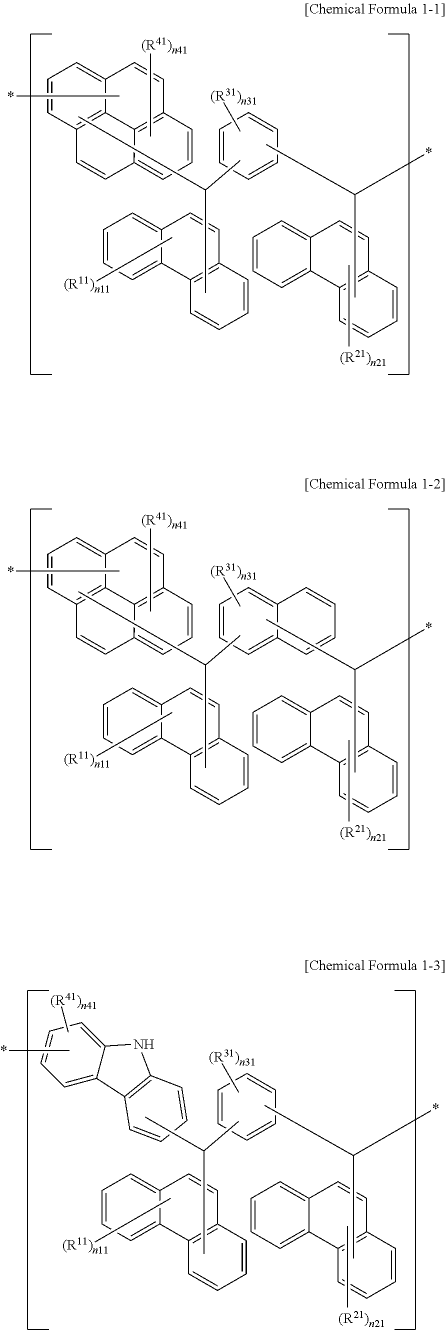

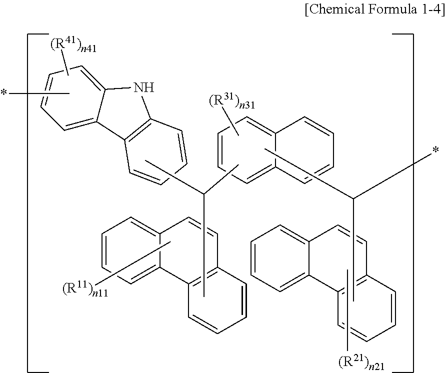

In Chemical Formula 1-1 to Chemical Formula 1-4, R¹¹ to R⁴¹ may each independently be, e.g., deuterium, a hydroxy group, a halogen atom, a substituted or unsubstituted C1 to C20 alkoxy group, a substituted or unsubstituted C1 to C20 alkyl group, a substituted or unsubstituted C6 to C20 aryl group, or a combination thereof. n11 to n41 may each independently be, e.g., an integer greater than or equal to 0, and are an integer of less than or equal to a bond valency of the ring in which R¹¹ to R⁴¹ are substituted.

In an implementation, R¹¹ to R⁴¹ may each independently be, e.g., a hydroxy group or a substituted or unsubstituted C1 to C20 alkoxy group, for example, a hydroxy group or a substituted or unsubstituted C1 to C10 alkoxy group.

In an implementation, n11 to n41 may each independently be, e.g., an integer of 0 to 5, 0 to 3, 0, or 1.

In an implementation, Chemical Formula 1 may be represented by, e.g., one of Chemical Formula 1-5 to Chemical Formula 1-8.

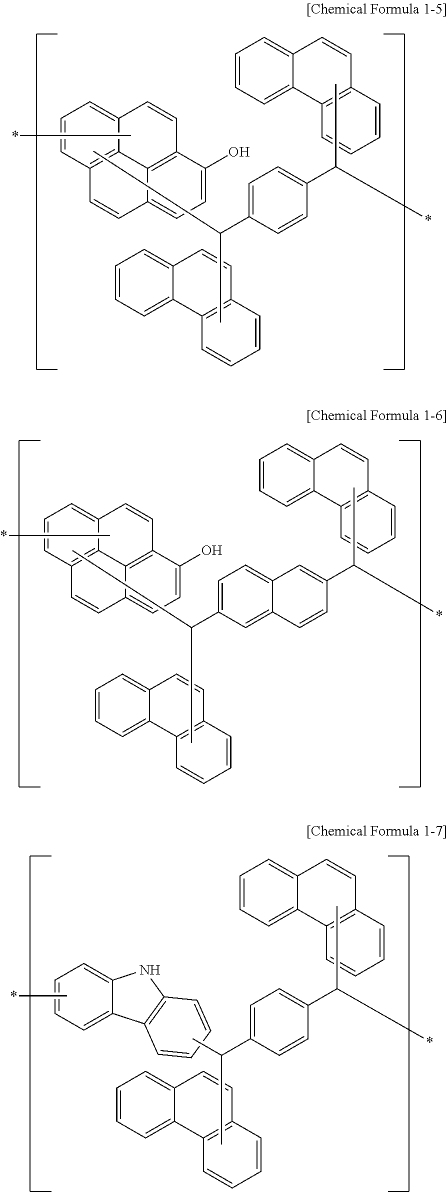

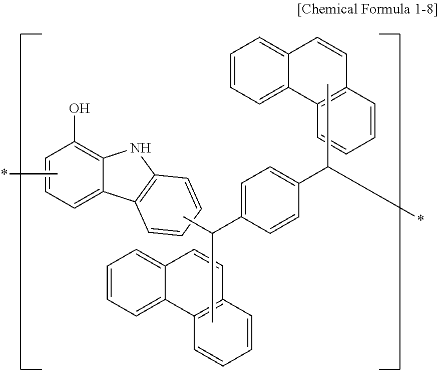

The polymer may have a weight average molecular weight of, e.g., about 500 g/mol to about 200,000 g/mol. In an implementation, the polymer may have a weight average molecular weight of about 500 g/mol to about 150,000 g/mol, e.g., about 500 g/mol to about 100,000 g/mol, about 700 g/mol to about 50,000 g/mol, or about 700 g/mol to about 10,000 g/mol. By having a weight average molecular weight within the above ranges, the carbon content and solubility in the solvent of the hardmask composition including the above polymer may be adjusted and optimized.

The polymer may be included in an amount of, e.g., about 0.01 wt % to about 30 wt % based on a total weight of the hardmask composition. In an implementation, the polymer may be included in an amount of about 0.02 wt % to about 30 wt %, e.g., about 0.05 wt % to about 30 wt %, about 0.1 wt % to about 30 wt %, about 0.2 wt % to about 25 wt %, or about 0.5 wt % to about 20 wt %. By including the polymer within the above ranges, a thickness, a surface roughness, and a planarization degree of the hardmask may be easily adjusted.

The hardmask composition according to some embodiments may include a solvent. In an implementation, the solvent may include propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. The solvent may be a suitable solvent having sufficient solubility and/or dispersibility with respect to the polymer.

In an implementation, the hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine crosslinking agent, a substituted urea crosslinking agent, or a polymer crosslinking agent. In an implementation, it may be a crosslinking agent having at least two crosslinking substituents, e.g., compounds such as methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer is a material to be finally patterned, e.g. a metal layer such as an aluminum layer and a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, for example, a first heat-treating process, and a second heat-treating process.

In an implementation, the heat-treating of the hardmask composition may include, e.g., one heat-treating process performed at about 100° C. to about 1000° C. for about 10 seconds to about 1 hour. In an implementation, the heat-treating may be performed under an atmosphere of air or nitrogen, or an atmosphere having oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or 30 seconds to about 5 minutes.

In an implementation, the heat-treating may include a second heat-treating process that is consecutively performed, e.g., at about 100° C. to about 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to 5 minutes. In an implementation, the first and second heat-treating processes may be performed under an air or nitrogen atmosphere, or may be performed in an atmosphere with an oxygen concentration of about 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process and/or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of a material, e.g. SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of pattern may include a metal pattern, a semiconductor pattern, an insulation pattern, or the like, e.g. diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymer

### Comparative Synthesis Example 1

36.0 g (0.2 mol) of phenanthrene and 20.2 g (0.1 mol) of terephthaloyl chloride were added to a 500 ml 2-necked flask equipped with a mechanical stirrer and a cooling tube and then, dissolved in 435 g of dichloroethane. After 15 minutes, 15 g (0.25 mol) of trichloroaluminum was slowly added thereto, and the mixed solution was reacted at 10 to 15° C. for 3 hours. When the reaction was completed, after using water to remove the trichloroaluminum, an evaporator was used for concentration. Subsequently, 270 g of tetrahydrofuran was added to the obtained compound, obtaining a solution. Then, an aqueous solution of 14.9 g (0.42 mol) of sodium borohydride was slowly added to the solution and then stirred at ambient temperature for 24 hours. When the reaction was completed, the resultant was acidified to pH 5 with a 1% hydrogen chloride solution and extracted with ethyl acetate, and an organic solvent was removed under a reduced pressure, obtaining Compound A represented by Chemical Formula A.

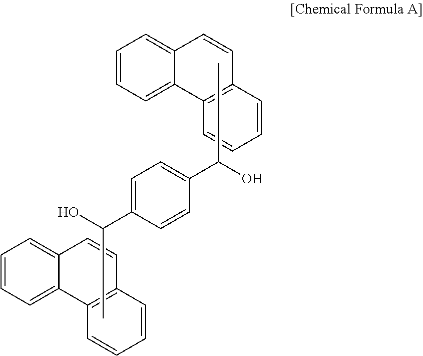

### Comparative Synthesis Example 2

Compound B represented by Chemical Formula B was obtained in the same manner as in Comparative Synthesis Example 1 except that 0.1 mol of 2,6-naphthalenedicarbonyl dichloride was used instead of the terephthaloylchloride.

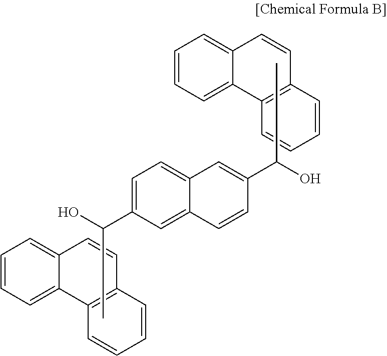

### Synthesis Example 1

50 g (0.11 mol) of Compound A, 23.8 g (0.11 mol) of 1-hydroxypyrene, 0.14 g (0.02 mol) of paratoluenesulfonic acid, and 172 g of 1,4-dioxane were added to a 500 ml 2-necked flask equipped with a mechanical stirrer and a cooling tube and then, well stirred and after increasing a temperature to 100° C., stirred again for 20 hours. When a reaction was completed, after decreasing an internal temperature thereof to ambient temperature, 300 g of tetrahydrofuran was added thereto to prevent the compound from hardening, and a 7% sodium bicarbonate aqueous solution was used to adjust pH to 5 or 6. Subsequently, after pouring 1,000 ml of ethyl acetate thereinto, while continuously stirring, an organic layer alone was extracted therefrom by using a separatory funnel. After repeating three times or more a process of adding 500 ml of water to the separatory funnel again and shaking it to remove any remaining acid and sodium, the organic layer was finally extracted. Subsequently, the organic solution was concentrated by using an evaporator, and 700 g of tetrahydrofuran was added to the obtained compound, obtaining the compound in a solution state. This solution was slowly added dropwise to a beaker containing 3,000 ml of hexane, while stirring, to form a precipitate, thereby, obtaining Polymer 1 including structural units represented by Chemical Formula 1-5. Polymer 1 was measured with respect to a weight average molecular weight (Mw) and polydispersity (PD) by using gel permeation chromatography (GPC). (Mw: 2,400 g/mol, PD: 1.56)

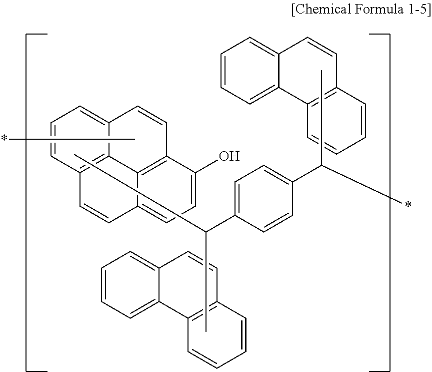

### Synthesis Example 2

Polymer 2 (including structural units represented by Chemical Formula 1-6) was obtained in the same manner as in Synthesis Example 1 except that 0.11 mol of Compound B was used instead of Compound A. Polymer 2 was measured with respect to a weight average molecular weight (Mw) and polydispersity (PD) by using gel permeation chromatography (GPC). (Mw: 2,510 g/mol, PD: 1.52)

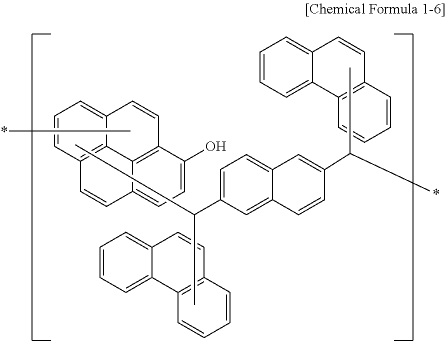

### Synthesis Example 3

Polymer 3 (including structural units represented by Chemical Formula 1-7) was obtained in the same manner as in Synthesis Example 1 except that 0.11 mol of carbazole was used instead of the 1-hydroxypyrene. Polymer 3 was measured with respect to a weight average molecular weight (Mw) and polydispersity (PD) by using gel permeation chromatography (GPC). (Mw: 2,280 g/mol, PD: 1.47)

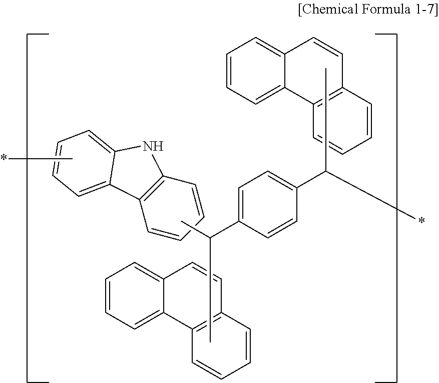

### Synthesis Example 4

Polymer 4 (including structural units represented by Chemical Formula 1-8) was obtained in the same manner as in Synthesis Example 1 except that 0.11 mol of 1-hydroxycarbazole was used instead of the 1-hydroxypyrene. Polymer 4 was measured with respect to a weight average molecular weight (Mw) and polydispersity (PD) by using gel permeation chromatography (GPC). (Mw: 2,280 g/mol, PD: 1.47)

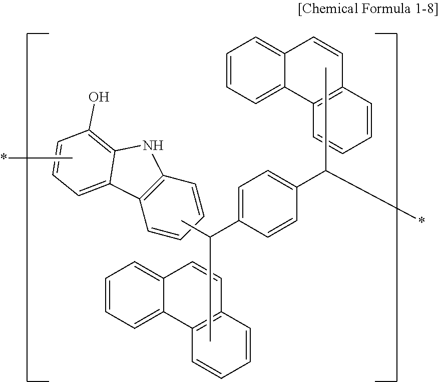

### Preparation of Hardmask Composition

### Example 1

1.2 g of Polymer 1 according to Synthesis Example 1 was dissolved in 10 g of a mixed solvent of propylene glycolmonomethyl etheracetate (PGMEA) and propylene glycolmonomethylether (PGME) (7:3 (v/v)) and then, filtered with a 0.1 μm TEFLON (tetrafluoroethylene) filter to prepare a hardmask composition according to Example 1.

### Example 2

A hardmask composition according to Example 2 was prepared in the same manner as in Example 1 except that Polymer 2 was used instead of Polymer 1.

### Example 3

A hardmask composition according to Example 3 was prepared in the same manner as in Example 1 except that Polymer 3 was used instead of Polymer 1.

### Example 4

A hardmask composition according to Example 4 was prepared in the same manner as in Example 1 except that Polymer 4 was used instead of Polymer 1.

### Comparative Example 1

1.5 g of Compound A according to Comparative Synthesis Example 1 was dissolved in 10 g of a mixed solvent of propylene glycol monomethylether acetate (PGMEA) and cyclohexanone (7:3 (v/v)) and then, filtered with a 0.1 μm TEFLON (tetrafluoroethylene) filter to prepare a hardmask composition according to Comparative Example 1.

### Comparative Example 2

A hardmask composition was prepared in the same manner as in Comparative Example 1 except that Compound B according to Comparative Synthesis Example 2 was used instead of Compound A.

### Evaluation 1: Etch Resistance Evaluation

Each of the hardmask compositions of Examples 1 to 4 and Comparative Examples 1 to 2 was spin-on coated on a silicon wafer and then, heat-treated on a hot plate at 400° C. for 2 minutes to form a 4,000 Å-thick thin film. Subsequently, the thin film was measured with respect to a thickness by using a thin film thickness-measuring device made by K-MAC. Subsequently, the thin film was dry-etched by using a mixed gas of CF₄/CHF₃ for 100 seconds and then, measured again with respect to a thickness. The thicknesses before and after dry-etching the thin film were used with etching time to calculate a bulk etch rate (BER) according to Calculation Equation 1, and the results are shown in Table 1.

$$Etch rate ( Å / sec ) = ( Initial thin film thickness - Thin film thickness after etching ) / Etching time \qquad [ Calculation Equation 1 ]$$

TABLE 1

| | Bulk etch rate (Å/sec) |
|---|---|
| | CFₓ/CHFₓ Etch |
| Example 1 | 24.2 |
| Example 2 | 23.7 |
| Example 3 | 24.6 |
| Example 4 | 25.0 |
| Comparative Example 1 | 27.2 |
| Comparative Example 2 | 26.8 |

Referring to Table 1, the hardmask layers respectively formed of the hardmask compositions according to Examples 1 to 4, compared with the hardmask layers respectively formed of the hardmask compositions according to Comparative Examples 1 to 2, exhibited a low etch rate to the mixed gas of CF₄/CHF₃ and thus excellent etch resistance.

### Evaluation 2: Solubility Evaluation

Polymers 1 to 4 and Compounds A and B according to the Synthesis Examples and the Comparative Synthesis Examples were respectively added to 20 g of propylene glycolmonomethyl ether acetate (hereinafter, PGMEA) to check solubility. The solubility was evaluated by measuring an amount of each of the polymers or the compounds in 20 g of the solvent and then, converting it to a percentage according to Calculation Equation 2. The results are shown in Table 2.

$$Solubility ( \% ) = \{ mass of polymer or compound ( g ) / mass of solvent ( 20 g ) \} \qquad [ Calculation Equation 2 ]$$

TABLE 2

| | Solubility (%) |
|---|---|
| Synthesis Example 1 | 42 |
| Synthesis Example 2 | 45 |
| Synthesis Example 3 | 30 |
| Synthesis Example 4 | 35 |
| Comparative Synthesis Example 1 | 10 |
| Comparative Synthesis Example 2 | 19 |

Referring to Table 2, the polymers according to the Synthesis Examples exhibited larger solubility in PGMEA than the compounds according to the Comparative Synthesis Examples.

### Evaluation 3: Film Density Evaluation

The hardmask compositions according to Examples 1 to 4 and Comparative Examples 1 to 2 were spin-on coated on a silicon wafer and then heat-treated at 400° C. for 2 minutes on a hot plate to form hardmask layers with each thickness of 1,000 Å. The film density of the hardmask layers was measured by using X-ray diffraction equipment from PANalytical Ltd., and the results are shown in Table 3.

TABLE 3

| | Film density (g/cm³) |
|---|---|
| Example 1 | 1.40 |
| Example 2 | 1.39 |
| Example 3 | 1.35 |
| Example 4 | 1.38 |
| Comparative Example 1 | 1.25 |
| Comparative Example 2 | 1.26 |

Referring to Table 3, the hardmask layers formed of the hardmask compositions of Examples 1 to 4 exhibited larger density and more excellent physical properties than the hardmask layers formed of the hardmask compositions according to Comparative Examples 1 to 2.

By way of summation and review, according to small-sizing the pattern to be formed, it may be difficult to provide a fine pattern having an excellent profile by using some lithographic techniques. Accordingly, an auxiliary layer, called a hardmask layer, may be formed between the material layer and the photoresist layer to provide a fine pattern.

One or more embodiments may provide a hardmask composition that can be effectively applied to a hardmask layer.

The hardmask composition according to some embodiments may have excellent solubility in solvents and can be effectively applied to a hardmask layer.

A hardmask layer formed from a hardmask composition according to some embodiments may help secure excellent etch resistance and excellent pattern formation properties.

The hardmask layer formed from the hardmask composition according to some embodiments may have a high film density, so that physical properties of the film may be improved.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent, 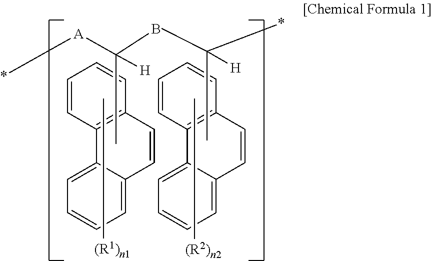
wherein, in Chemical Formula 1,
A is a substituted or unsubstituted moiety of Group 1,
B is a substituted or unsubstituted phenylenyl group or a substituted or unsubstituted naphthalenyl group,
R¹ and R² are each independently deuterium, a hydroxy group, a halogen atom, —NR^{a}R^{b}, in which R^{a} and R^{b} are each independently hydrogen, deuterium, a substituted or unsubstituted C1 to C10 alkyl group, or a substituted or unsubstituted C6 to C20 aryl group, a substituted or unsubstituted C1 to C20 alkoxy group, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic hydrocarbon group, a substituted or unsubstituted C6 to C30 hetero aromatic hydrocarbon group, or a combination thereof,
n1 and n2 are each independently an integer of 0 to 9, and
* is a linking point, 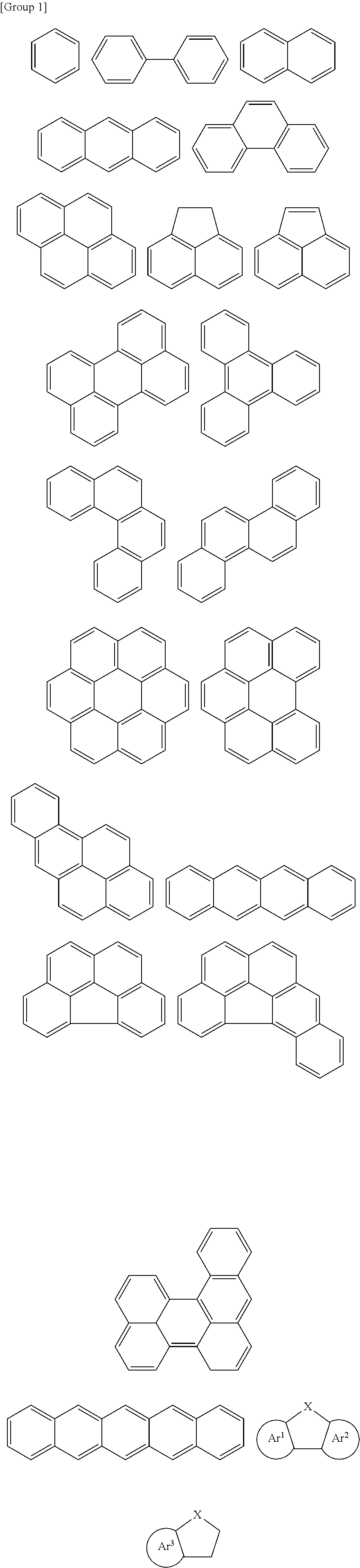
wherein, in Group 1,
Ar¹ to Ar³ are each independently a substituted or unsubstituted C6 to C20 aromatic ring group,
X is —CR^{c}R^{d}—, —N(R^{e})—, —B(R^{f})—, —P(R^{g})—, —O—, or —S—, and
R^{e} to R^{g} are each independently hydrogen, deuterium, a substituted or unsubstituted C1 to C10 alkyl group, a substituted or unsubstituted C6 to C20 aryl group, or a combination thereof.

2. The hardmask composition as claimed in claim 1, wherein:
A is a substituted or unsubstituted moiety of Group 1-1: 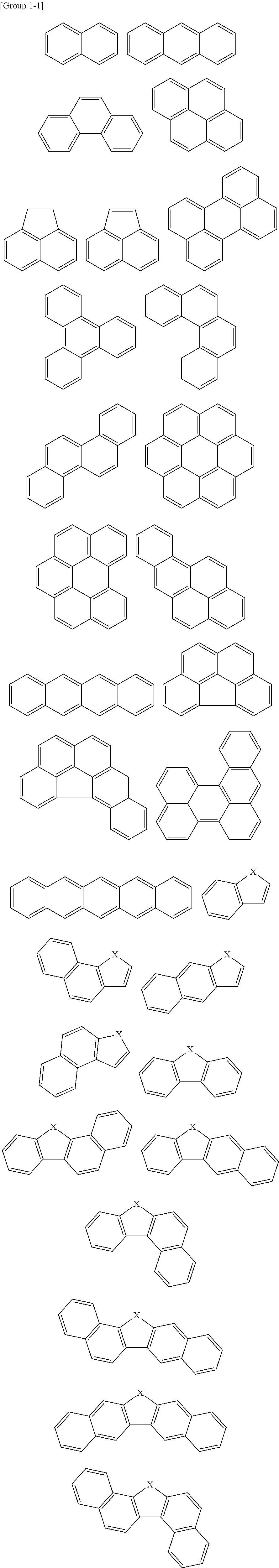
in Group 1-1,
X is —CR^{c}R^{d}—, —N(R^{e})—, —O—, or —S—, and
R^{c} to R^{e} are each independently hydrogen, deuterium, a substituted or unsubstituted C1 to C10 alkyl group, a substituted or unsubstituted C6 to C20 aryl group, or a combination thereof.

3. The hardmask composition as claimed in claim 1, wherein A is a substituted or unsubstituted moiety of Group 1-2:

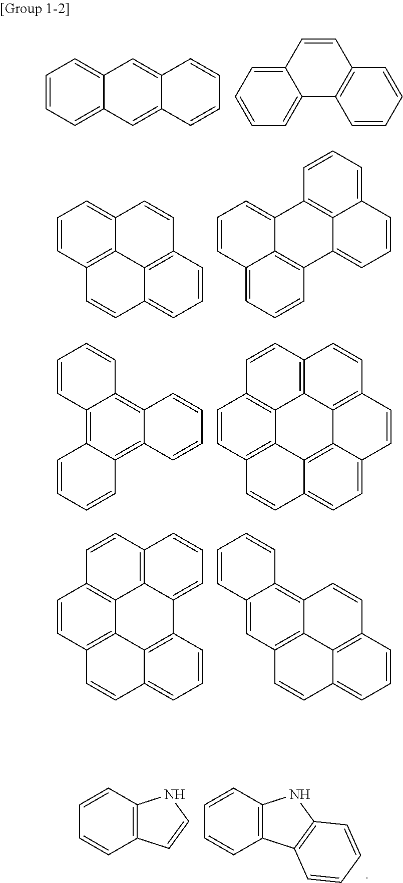

4. The hardmask composition as claimed in claim 1, wherein:
R¹ and R² are each independently deuterium, a hydroxy group, a halogen atom, —NR^{a}R^{b}, in which R^{a} and R^{b} are each independently hydrogen, deuterium, or a substituted or unsubstituted C1 to C10 alkyl group, a substituted or unsubstituted C1 to C20 alkoxy group, a substituted or unsubstituted C1 to C20 alkyl group, a substituted or unsubstituted C2 to C20 alkenyl group, a substituted or unsubstituted C3 to C20 cycloalkyl group, a substituted or unsubstituted C3 to C20 cycloalkenyl group, a substituted or unsubstituted C1 to C20 heteroalkyl group, a substituted or unsubstituted C2 to C20 heterocycloalkyl group, a substituted or unsubstituted C6 to C30 aryl group, a substituted or unsubstituted C2 to C20 heteroaryl group, or a combination thereof, and
n1 and n2 are each independently an integer of 0 to 4.

5. The hardmask composition as claimed in claim 1, wherein:
R¹ and R² are each independently deuterium, a hydroxy group, a halogen atom, a substituted or unsubstituted C1 to C20 alkoxy group, a substituted or unsubstituted C1 to C20 alkyl group, a substituted or unsubstituted C6 to C20 aryl group, or a combination thereof, and
n1 and n2 are each independently 0 or 1.

6. The hardmask composition as claimed in claim 1, wherein:
Chemical Formula 1 is represented by one of Chemical Formula 1-1 to Chemical Formula 1-4: 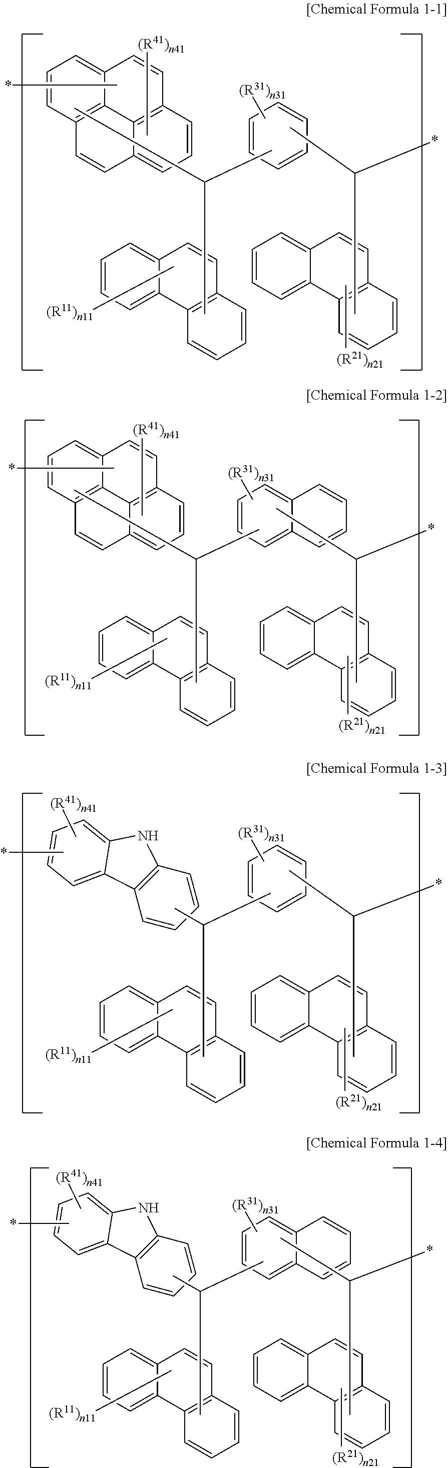
in Chemical Formula 1-1 to Chemical Formula 1-4,
R¹¹ to R⁴¹ are each independently deuterium, a hydroxy group, a halogen atom, a substituted or unsubstituted C1 to C20 alkoxy group, a substituted or unsubstituted C1 to C20 alkyl group, a substituted or unsubstituted C6 to C20 aryl group, or a combination thereof, and
n11 to n41 are each independently an integer greater than or equal to 0, and are an integer of less than or equal to a bond valency of a ring on which R¹¹ to R⁴¹ are substituted.

7. The hardmask composition as claimed in claim 1, wherein Chemical Formula 1 is represented by one of Chemical Formula 1-5 to Chemical Formula 1-8:

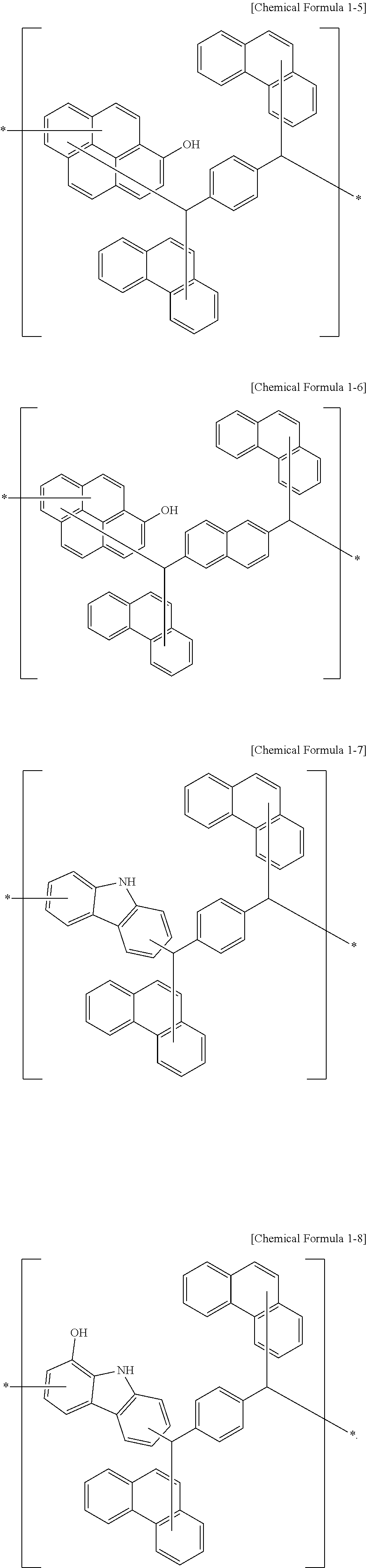

8. The hardmask composition as claimed in claim 1, wherein a weight average molecular weight of the polymer is about 500 g/mol to about 200,000 g/mol.

9. The hardmask composition as claimed in claim 1, wherein the polymer is included in an amount of about 0.01 wt % to about 30 wt %, based on a total weight of the hardmask composition.

10. The hardmask composition as claimed in claim 1, wherein the solvent is propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

11. A hardmask layer comprising a cured product of the aforementioned hardmask composition as claimed in claim 1.

12. A method of forming patterns, the method comprising:
providing a material layer on a substrate,
applying the hardmask composition as claimed in claim 1 to the material layer,
heat-treating the hardmask composition to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed part of the material layer.

13. The method as claimed in claim 12, wherein forming the hardmask layer includes heat-treating at about 100° C. to about 1,000° C.
